(19) United States
(12) Patent Application Publication
(10) Pub. No.: US 2011/0215413 A1
(43) Pub. Date: Sep. 8, 2011

(54) SEMICONDUCTOR DEVICE AND METHOD FOR MANUFACTURING THE SAME

(76) Inventor: Daisuke IKENO, Yokohama-Shi (JP)

(21) Appl. No.: 13/025,695

(22) Filed: Feb. 11, 2011

(30) Foreign Application Priority Data
Mar. 4, 2010 (JP) 2010-47930

(51) Int. Cl. H01L 27/092; H01L 21/8238

(52) U.S. Cl. 257/369; 438/216; 257/E27.067; 257/E21.639

(57) ABSTRACT

According to one embodiment, a semiconductor device includes an N-type transistor and a P-type transistor. The N-type transistor has a first gate insulating film comprising a high dielectric film on a semiconductor substrate, and a first gate electrode comprising a TaₓN_{y} film comprising Ta₃N₅ on the first gate insulating film. The first gate insulating film comprises a first material decreasing an effective work function of the first gate electrode. The P-type transistor has a SiGe film on the semiconductor substrate, a second gate insulating film comprising the high dielectric film on the SiGe film, and a second gate electrode on the second gate insulating film, the second gate electrode being made of a material identical to a material of the first gate electrode. The second gate insulating film comprises a second material increasing an effective work function of the second gate electrode.

### CROSS REFERENCE TO RELATED APPLICATIONS

This application is based upon and claims the benefit of priority from the prior Japanese Patent Application No. 2010-47930, filed on Mar. 4, 2010, the entire contents of which are incorporated herein by reference.

### FIELD

Embodiments described herein relate generally to a semiconductor device and a method for manufacturing the same.

### BACKGROUND

In order to realize a high-speed operation in a logic circuit using CMOS (Complementary Metal-Oxide-Semiconductor) transistors, it is necessary to decrease threshold voltages Vth of an NMOSFET (Negative-channel Metal-Oxide-Semiconductor Field-Effect-Transistor) and a PMOSFET (Positive-channel Metal-Oxide-Semiconductor Field-Effect-Transistor).

Conventionally, a semiconductor such as polysilicon (Poly-Si) is used as a material of a gate electrode. When the material of the gate electrode is the semiconductor, the threshold voltage Vth of the NMOSFET can be more decreased as a Fermi level of the gate electrode is closer to the conduction band minimum 4.05 eV of silicon which is material of a substrate. Furthermore, the threshold voltage Vth of the PMOSFET 200 can be more decreased as the Fermi level of the gate electrode is closer to the valence band maximum 5.17 eV. The reason is that as the Fermi level of the gate electrode is closer to the conduction band minimum or the valence band maximum, it needs a lower gate voltage to form an inversion layer on a channel. If the material of the gate electrode is the semiconductor, the Fermi level can be adjusted easily by controlling an impurity concentration, for example.

In recent years, for miniaturization of the transistors, there have been often used a transistor having a metal gate electrode whose material is not the polysilicon but a metal. When the material of the gate electrode is the metal, the threshold voltage Vth can be more decreased as an effective work function, which corresponds to the Fermi level of the semiconductor, is closer to the conduction band minimum or the valence band maximum.

Because the effective work function depends on a work function unique to each metal, by using a metal whose effective work function is approximately 4.05 eV for the NMOSFET and by a metal whose effective work function is approximately 5.17 eV for the PMOSFET, it is considered that the threshold voltages Vth can be decreased. However, in order to reduce a manufacturing cost, it is necessary to use the same material for the metal gate electrode of the NMOSFET and that of the PMOSFET. Therefore, an optimum metal cannot be always selected.

As the material of the metal gate electrode, TiN (titanium nitride) is generally used because the TiN is thermally stable and easily processed (for example, “Achieving Conduction Band-Edge Effective Work Function by La₂O₃ Capping of Hafnium Slicates”, Lars-Ake Ragnarsson et al, IEEE Electron Device Letters, Vol. 28, No. 6, June 2007). However, it is difficult to adjust the effective work function of the TiN to the conduction band minimum 4.05 eV and the valence band maximum 5.17 eV, and there is a problem that the threshold voltage Vth cannot be decreased enough.

Furthermore, in order to realize a low-power operation, it is necessary to further suppress a leak current of a gate insulating film comparing to a case where the material of the metal gate electrode is TiN.

### BRIEF DESCRIPTION OF THE DRAWINGS

FIG. 1 is a sectional view of a semiconductor device 500 according to a first embodiment.

FIG. 2 is a graph showing a relationship between a composition ratio of the TaₓN_{y} in a MOS capacitor having a stacked structure of polysilicon/TaₓN_{y}/HfSiON/SiON/Si and a flat band voltage Vfb.

FIG. 3 is a graph showing a relationship between the composition ratio of the TaₓN_{y} in a MOS capacitor having a stacked structure of polysilicon/TaₓN_{y}/HfSiON/SiON/Si and a leak current Jg.

FIG. 4 is a graph showing a relationship between the composition ratio of the TaₓN_{y} in a MOS capacitor having a stacked structure of polysilicon/TaₓN_{y}/HfSiON/SiON/Si and an accumulated capacitor converted gate insulating film thickness Tacc.

FIG. 5 is a process chart showing the steps of a manufacturing process for the semiconductor device 500 of FIG. 1.

FIG. 6 is a sectional view of the semiconductor device 500 in its manufacturing process.

FIG. 7 is a sectional view of the semiconductor device 500 in its manufacturing process following FIG. 6.

FIG. 8 is a sectional view of the semiconductor device 500 in its manufacturing process following FIG. 7.

FIG. 9 is a sectional view of the semiconductor device 500 in its manufacturing process following FIG. 8.

FIG. 10 is a sectional view of the semiconductor device 500 in its manufacturing process following FIG. 9.

FIG. 11 is a sectional view of the semiconductor device in its manufacturing process following FIG. 10.

FIG. 12 is a sectional view of the semiconductor device which is a first modification example in its manufacturing process.

FIG. 13 is a sectional view of the semiconductor device which is a second modification example in its manufacturing process.

FIG. 14 is a sectional view of the semiconductor device which is a third modification example in its manufacturing process.

FIG. 15 is a sectional view of a semiconductor device 500a according to the second embodiment.

FIG. 16 is process chart showing the steps of a manufacturing process for the semiconductor device 500a of FIG. 15.

FIG. 17 is a sectional view of the semiconductor device 500a in its manufacturing process.

FIG. 18 is a sectional view of the semiconductor device 500a in its manufacturing process following FIG. 17.

FIG. 19 is a sectional view of the semiconductor device which is a modification example of FIG. 18 in its manufacturing process.

FIG. 20 is a sectional view of the semiconductor device 500a in its manufacturing process following FIG. 18.

FIG. 21 is a sectional view of the semiconductor device 500a in its manufacturing process following FIG. 20.

### DETAILED DESCRIPTION

In general, according to one embodiment, a semiconductor device includes an N-type transistor and a P-type transistor. The N-type transistor has a first gate insulating film comprising a high dielectric film on a semiconductor substrate, and a first gate electrode comprising a TaₓN_{y} film comprising Ta₃N₅ on the first gate insulating film. The first gate insulating film comprises a first material decreasing an effective work function of the first gate electrode. The P-type transistor has a SiGe film on the semiconductor substrate, a second gate insulating film comprising the high dielectric film on the SiGe film, and a second gate electrode on the second gate insulating film, the second gate electrode being made of a material identical to a material of the first gate electrode. The second gate insulating film comprises a second material increasing an effective work function of the second gate electrode.

Embodiments will now be explained with reference to the accompanying drawings.

### First Embodiment

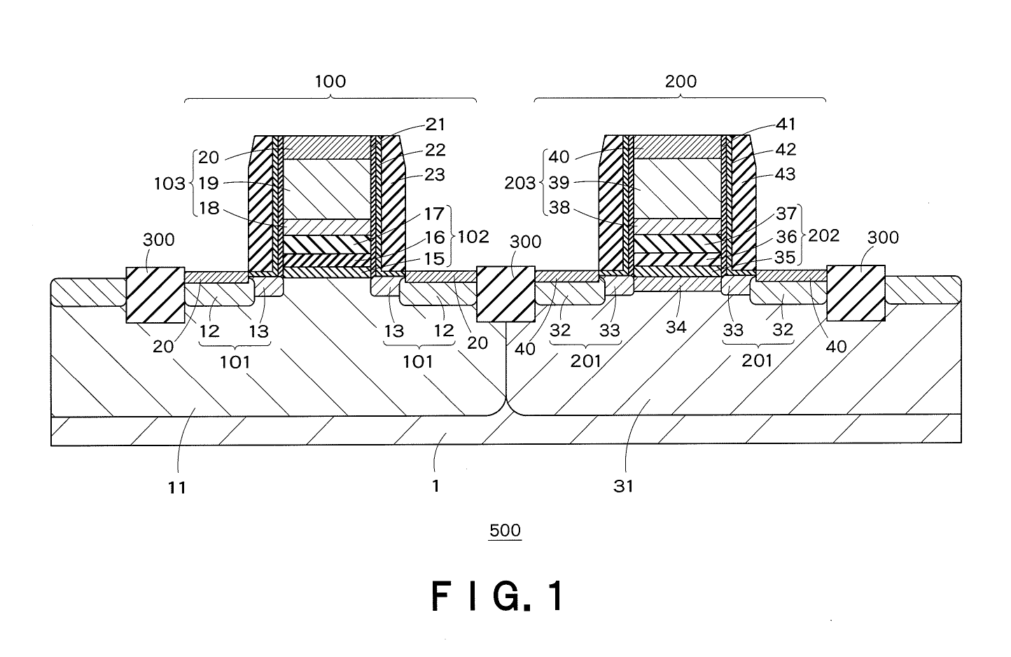

FIG. 1 is a sectional view of a semiconductor device 500 according to a first embodiment. The semiconductor device 500 has, on a silicon substrate 1, an NMOSFET 100, a PMOSFET 200, and element isolation regions 300 for separating the NMOSFET 100 and the PMOSFET 200 electrically.

The NMOSFET 100 has a P-type diffusion layer 11, an N-type diffusion layer 12, an N-type extension diffusion layer 13, a SiON (silicon nitride and oxide) film 15, a La₂O₃ (lanthanum oxide) film 16, HfSiON (hafnium silicon nitride and oxide) film 17, a TaₓN_{y} (tantalum nitride) film 18, a silicon film 19, a silicide film 20, offset spacers 21, and side wall spacers 22 and 23.

A channel is formed on a surface of the P-type diffusion layer 11 right under the SiON film 15, and a source region is formed at one side of the channel and a drain region is formed at the other end of the channel. Hereinafter, the source region and the drain region are referred to as a source/drain region as a whole. The source/drain region is formed by the N-type diffusion layer 12 and the N-type extension diffusion layer 13. A stacked-structured gate insulating film 102 having the stacked SiON film 15, the La₂O₃ film 16 and the HfSiON film 17 is formed on the channel region. Here, the HfSiON film 17 is a high dielectric (High-K) film. On the gate insulating film 102, a stacked-structured metal gate electrode 103 having the stacked TaₓN_{y} film 18, the silicon film 19 and the silicide film 20 is formed.

On the other hand, the PMOSFET 200 has an N-type diffusion layer 31, a P-type diffusion layer 32, a P-type extension diffusion layer 33, an epitaxial SiGe (silicon germanium) film 34, a SiON film 35, a Al₂O₃ (aluminum oxide) film 36, HfSiON film 37, a TaₓN_{y} film 38, a silicon film 39, a silicide film 40, offset spacers 41, and side wall spacers 42 and 43.

A channel is formed on a surface of the N-type diffusion layer 31 right under the SiON film 35, and a source/drain region 201 formed by the P-type diffusion layer 32 and the P-type extension diffusion layer 33 is formed at both side of the channel. A stacked-structured gate insulating film 202 having the stacked SiON film 35, the Al₂O₃ film 36 and the HfSiON film 37 is formed on the channel region. On the gate insulating film 202, a stacked-structured metal gate electrode 203 having the stacked TaₓN_{y} film 38, the silicon film 39 and the silicide film 40 is formed.

As described above, the material of the metal gate electrode 103 is same as that of the metal gate electrode 203. Furthermore, the TaₓN_{y} film 18 and the TaₓN_{y} film 38 both have Ta₃N₅, which will be described below.

Incidentally, a work function is unique to each metal, and in the following explanation, an effective work function (hereinafter, referred to as EWF) is a value corresponding to a Fermi level of a semiconductor and is determined by the work function unique to the metal and the material of the insulating film contacting with the metal and so on. As the EWF is closer to the conduction band minimum 4.05 eV and the valence band maximum 5.17 eV of the silicon, the threshold voltage Vth can be more decreased, thereby realizing a high-speed operation.

As shown in FIG. 1, the gate insulating film 102 of the NMOSFET 100 has the La₂O₃ film 16 inserted between the SiON film 15 and the HfSiON film 17. This structure decreases the EWF of the metal gate electrode 103 of the NMOSFET 100 by approximately 0.5 eV. The reason is considered that dipoles are formed due to a difference between electronegativity of the silicon and that of the lanthanum.

Furthermore, the gate insulating film 202 of the PMOSFET 200 has the Al₂O₃ film 36 inserted between the SiON film 35 and the HfSiON film 37. Additionally, the SiGe film 34 is formed on the channel region of the PMOSFET 200. These structures increase the EWF of the metal gate electrode 203 of the PMOSFET 200 by approximately 0.5 eV. The EWF is increased by forming the SiGe film 34 because the valence band maximum of the silicon decreases due to compression strain of the SiGe film 34 formed on the silicon substrate 1, and as a result, the EWF of the metal gate electrode 203 to the valence band maximum of the silicon relatively increases.

The reason to adjust the EWF is to decrease the threshold voltage Vth. In more detail, it is preferable that the material of the metal gate electrode 103 and that of the metal gate electrode 203 are the same in order to simplify the manufacturing process. The metal gate electrode is formed in advance so that the EWF before adjusted becomes near center between the conduction band minimum and the valence band maximum. Then, by the above adjustment, by increasing the EWF of the NMOSFET 100 and decreasing that of the PMOSFET 200, the EWF can be close to the conduction band minimum and the valence band maximum. As a result, the threshold voltage Vth can be decreased.

If the TiN, which is generally used, is used for the materials of the metal gate electrode 103 of the NMOSFET 100 and the metal gate electrode 203 of the PMOSFET 200, the EWF is 4.4 eV when the TiN is formed on the HfSiON film. By a structure having the Al₂O₃ film 36 inserted in the gate insulating film 202 of the PMOSFET 101, the EWF increases 0.5 eV and thus, the EWF of the metal gate electrode 203 is 4.4+0.5=4.9 eV. This value is lower than the valence band maximum of the silicon. In order to get the EWF of the metal gate electrode 203 close to the valence band maximum of the silicon, it is necessary to thicken the Al₂O₃ film 36, for example, which increases the effective thickness of the gate insulating film. Thus, if using the TiN as the materials of the metal gate electrodes 103 and 203, it is difficult to get the EWF close to the valence band maximum.

Therefore, in order to decrease the threshold voltage Vth of the transistor, it is necessary to select a material as the materials of the metal gate electrodes 103 and 203 which can increase the EWF more than the TiN. Consequently, in the present embodiment, it is one of the characteristic features that the TaₓN_{y} films 18 and 38 having the Ta₃N₅ are used as the materials of the metal gate electrode 103 of the NMOSFET 100 and the metal gate electrode 203 of the PMOSFET 200.

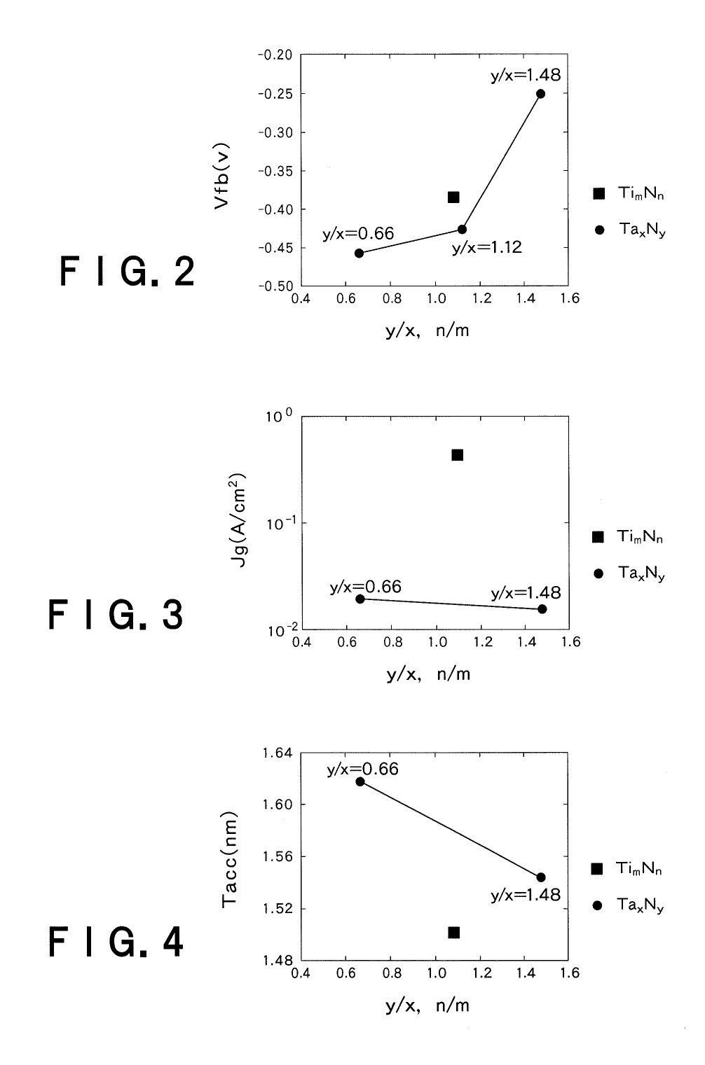

FIG. 2 is a graph showing a relationship between a composition ratio of the TaN in a MOS capacitor having a stacked structure of polysilicon/TaₓN_{y}/HfSiON/SiON/Si and a flat band voltage Vfb. For comparison, the flat band voltage Vfb is also plotted where the TiₘNₙ is used instead of the TaₓN_{y}. The horizontal axis of FIG. 2 shows the composition ratio “n/m” or “y/x”, and the vertical axis shows the flat band voltage Vfb. The composition ratios “n/m” and “y/x” are determined by RBS (Rutherford Back Scattering) manner. There is a positive correlative relationship between the flat band voltage Vfb and the EWE Therefore, the EWF can be increased by increasing the flat band voltage Vfb.

There are representative stable phases of the TaN such as Ta₂N (y/x=0.5), TaN (y/x=1), Ta₄N₅ (y/x=1.25) and Ta₃N₅ (y/x=1.67). The TaN (y/x=0.66) of FIG. 2 is considered to be formed mainly by Ta₂N and TaN, the TaN (y/x=1.12) is considered to be formed mainly by the TaN and the Ta₄N₅, the TaN (y/x=1.48) is considered to be formed mainly by the Ta₄N₅ and the Ta₃N₅. More generally, when 0.5≦y/x≦1, the TaₓN_{y} is formed mainly by the Ta₂N and TaN, when 1≦y/x≦y/x≦1.25, the TaₓN_{y} is formed mainly by the TaN and the Ta₄N₅, and when 1.25≦y/x≦1.67, the TaₓN_{y} is formed mainly by the Ta₄N₅ and the Ta₃N₅.

Different from the TiₘNₙ, there are stable phases of the TaₓN_{y} which has more nitrogen than tantalum such as the Ta₄N₅ and the Ta₃N₅. Therefore, the metal gate electrodes 103 and 203 can have much nitrogen. More specifically, by forming the TaₓN_{y} films 18 and 38 so that they have the Ta₃N₅, the composition ratio of the nitrogen can be more than 1.25. When the TaₓN_{y} films 18 and 38 has much nitrogen, a part of the nitrogen diffuses into the underlying HfSiON films 17 and 37 which are the gate insulating films, and negative charges are generated in the gate insulating films. As a result, it is considered that the flat band voltage Vfb increases.

Practically, as shown in FIG. 2, the flat band voltage Vfb of the metal gate electrode having the TaₓN_{y} (y/x=1.48) is higher than that having the TiₘNₙ or the TaₓN_{y} (y/x=0.66 or 1.12). Therefore, the EWF of the metal gate electrode can be increased, which can set the EWF of the metal gate electrodes 103 and 203 close to the conduction band minimum and the valence band maximum of the silicon, respectively, thereby decreasing the threshold voltages Vth of the transistors.

FIG. 3 is a graph showing a relationship between the composition ratio of the TaₓN_{y} in a MOS capacitor having a stacked structure of polysilicon/TaₓN_{y}/HfSiON/SiON/Si and a leak current Jg. For comparison, the leak current Jg is also plotted where the TiₘNₙ is used instead of the TaₓN_{y}. The horizontal axis of FIG. 3 is the same as that of FIG. 2, and the vertical axis shows the leak current Jg. By using TaₓN_{y} as the material of the metal gate, the leak current Jg can be decreased by a figure comparing to the leak current Jg when the TiₘNₙ is used.

When a part of the tantalum in the TaₓN_{y} films 18 and 38 interfuses into the underlying HfSiON films 17 and 37 or when there are interface reactions between the tantalum and the HfSiON films 17 and 37, combinations between the tantalum atoms and the oxygen atoms are formed, and HfTaSiON is formed in the HfSiON films 17 and 37. As a result, it is considered that a physical film thickness of the gate insulating film increases, which decreases the leak current Jg.

FIG. 4 is a graph showing a relationship between the composition ratio of the TaₓN_{y} in a MOS capacitor having a stacked structure of polysilicon/TaₓN_{y}/HfSiON/SiON/Si and an accumulated capacitor converted gate insulating film thickness Tacc. For comparison, the accumulated capacitor converted gate insulating film thickness Tacc is also plotted where the TiₘNₙ is used instead of the TaₓN_{y}. The horizontal axis of FIG. 4 is the same as that of FIG. 2, and the vertical axis shows that accumulated capacitor converted gate insulating film thickness Tacc. The accumulated capacitor converted gate insulating film thickness Tacc is a film thickness of the gate insulating film estimated by the accumulated capacitor. For miniaturization, it is preferable that the accumulated capacitor converted gate insulating film thickness Tacc is small.

The accumulated capacitor converted gate insulating film thickness Tacc increases when using the TaₓN_{y}, especially, when the composition ratio of the nitrogen is small such as y/x=0.66, comparing to when using the TiₘNₙ as the material of the metal gate electrode. The reason is that when the composition ratio of the nitrogen is small, the TaₓN_{y} is thermally unstable, and interface reactions between the tantalum and the underlying HfSiON film occur. By increasing the composition ratio of the nitrogen, it is possible to suppress increasing the accumulated capacitor converted gate insulating film thickness Tacc.

Thus, by using the TaₓN_{y} having much nitrogen, because too much tantalum does not interfuse into the HfSiON films 17 and 37 and so on, the leak current Jg can be decreased while suppressing increasing the accumulated capacitor converted gate insulating film thickness Tacc.

As stated above, by using not the TiN but the TaₓN_{y}, the flat band voltage Vfb increases, thereby decreasing the threshold voltage Vth of the transistor (FIG. 2). Furthermore, in order to increase the flat band voltage Vfb (FIG. 2) and to decrease the leak current Jg (FIG. 3) while suppressing increasing the accumulated capacitor converted gate insulating film thickness Tacc (FIG. 4), it is preferable that the composition ratio of the nitrogen in the TaₓN_{y} is higher.

Therefore, in the present embodiment, the TaₓN_{y} films 18 and 38 having Ta₃N₅ are used as the materials of the metal gate electrodes 103 and 203.

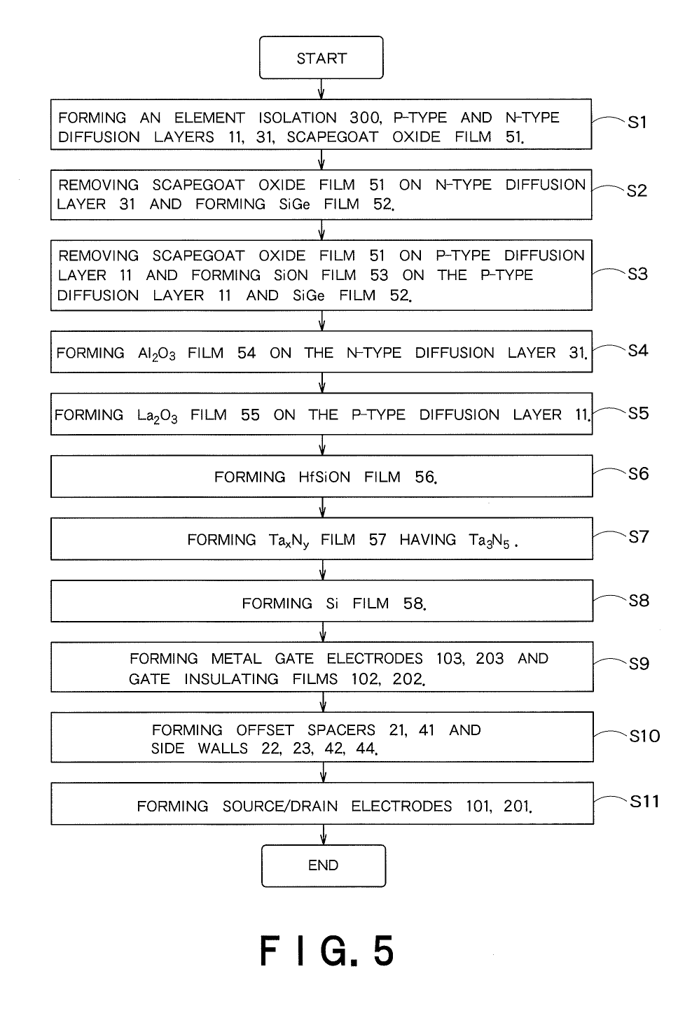

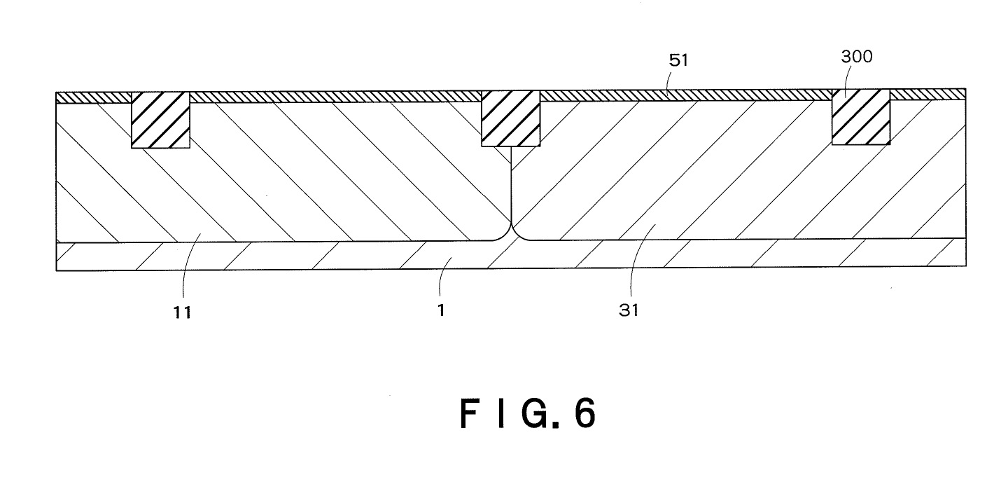

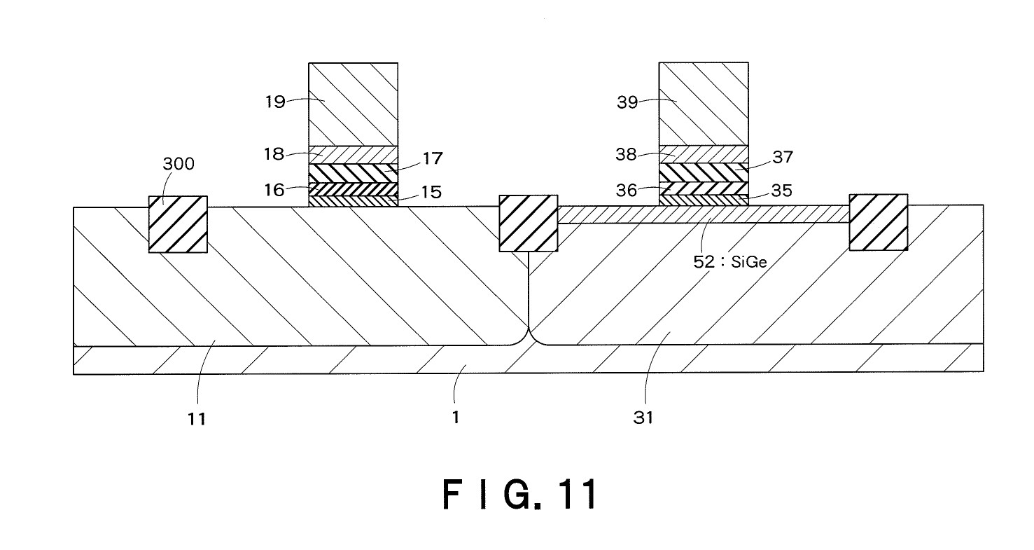

Hereinafter, a method for manufacturing the semiconductor device 500 according to the first embodiment will be explained. FIG. 5 is a process chart showing the steps of a manufacturing process for the semiconductor device 500 of FIG. 1. Each of FIGS. 6 to 11 is sectional view of the semiconductor device in its manufacturing process.

Firstly, multiple trenches are formed in the silicon substrate 1, STI (Shallow Trench Isolation)-structured element isolation regions 300 are formed by filling the trenches with insulating film. Secondly, the P-type diffusion layer 11 and the N-type diffusion layer 31 are formed in the silicon substrate 1. Furthermore, a scapegoat oxide film 51 is formed on the P-type diffusion layer 11 and the N-type diffusion layer 31 (Step S1). In this way, the cross section structure shown in FIG. 6 is obtained.

Then, using a resist film (not shown) as a mask, the scapegoat oxide film 51 on the N-type diffusion layer 31 is removed by NH₄F aqueous solution or diluted hydrofluoric acid.

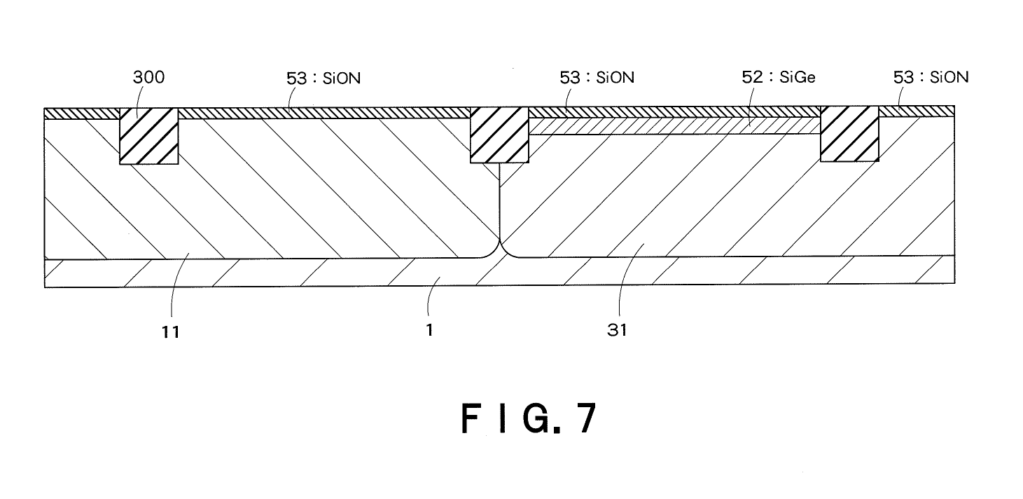

Because of this, the N-type diffusion layer 31 is exposed. Therefore, a SiGe film 52 is epitaxially grown on the surface of the N-type diffusion layer 31 selectively (Step S2). Next, the scapegoat oxide film 51 on the P-type diffusion layer 11 is removed as well, and a chemical SiO₂ film, having a film thickness of 1 nm for example, on the P-type diffusion layer 11 and the SiGe film 52. Then, after heat treatment under the atmosphere of oxygen and process under the atmosphere of nitrogen plasma, the heat treatment is performed again to mutate the SiO₂ film into a SiON film 53 (Step S3). In this way, the cross section structure shown in FIG. 7 is obtained.

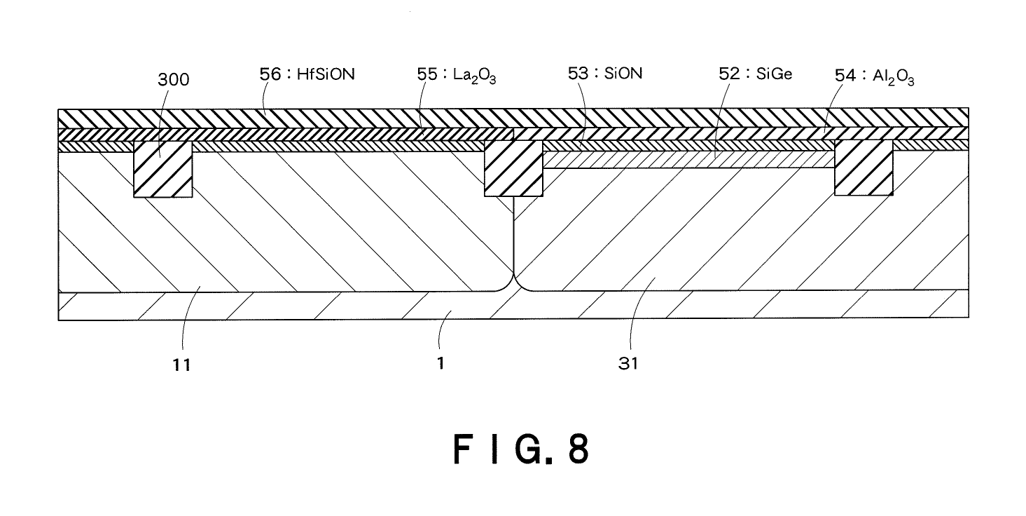

Then, by an ALD (Atomic Layer Deposition) manner or a PVD (Physical Vapor Deposition) manner, an Al₂O₃ film, having a film thickness of 1 nm for example, is formed on the whole surface. After that, using a resist film (not shown) as a mask, the Al₂O₃ film above the P-type diffusion layer 11 is removed by etching. Because of this, an Al₂O₃ film 54 is formed only on a side of the N-type diffusion layer 31 (Step S4, FIG. 8).

Then, by the PVD manner, a La₂O₃ film, having a film thickness of 1 nm for example, is formed on the whole surface. Next, using a resist film (not shown) as a mask, the La₂O₃ film above the N-type diffusion layer 31 is removed by etching. Because of this, a La₂O₃ film 55 is formed only on a side of the P-type diffusion layer 11 (Step S5, FIG. 8).

Then, by a MOCVD (Metal Organic Chemical Vapor Deposition) manner, a HfSiO (hafnium silicon oxide) film, having a film thickness of 2 nm for example, is formed on the whole surface. Furthermore, by performing the heat treatment after the process under the nitrogen plasma, the HfSiO film is mutated into a HfSiON film 56, which is the High-K layer (Step S6). In this way, the cross section structure shown in FIG. 8 is obtained.

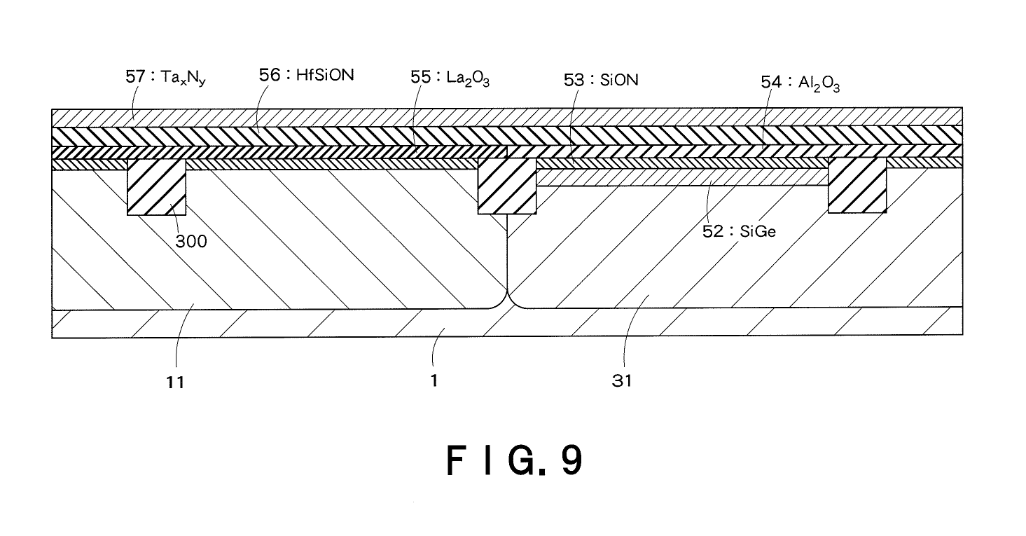

Then, by a reactive sputter manner using the tantalum as a target and nitrogen gas as reactive gas, a TaₓN_{y} film 57, having a film thickness of 10 nm for example, is formed (Step S7). If a flow volume of the nitrogen gas is small, the Ta₂N is mainly formed and the Ta₃N₅ is hardly formed. Therefore, the flow volume of the nitrogen gas is set large so as to form the TaₓN_{y} film 57 having the Ta₃N₅. In this way, the cross section structure shown in FIG. 9 is obtained.

By forming the TaₓN_{y} film 57 having much nitrogen, a part of the nitrogen diffuses into the HfSiON film 56 which becomes the gate insulating films 102 and 202 during the heat treatment, which will be described below. Therefore, the flat band voltage Vfb increases and the threshold voltages Vth of the NMOSFET 100 and the PMOSFET 200 can be decreased.

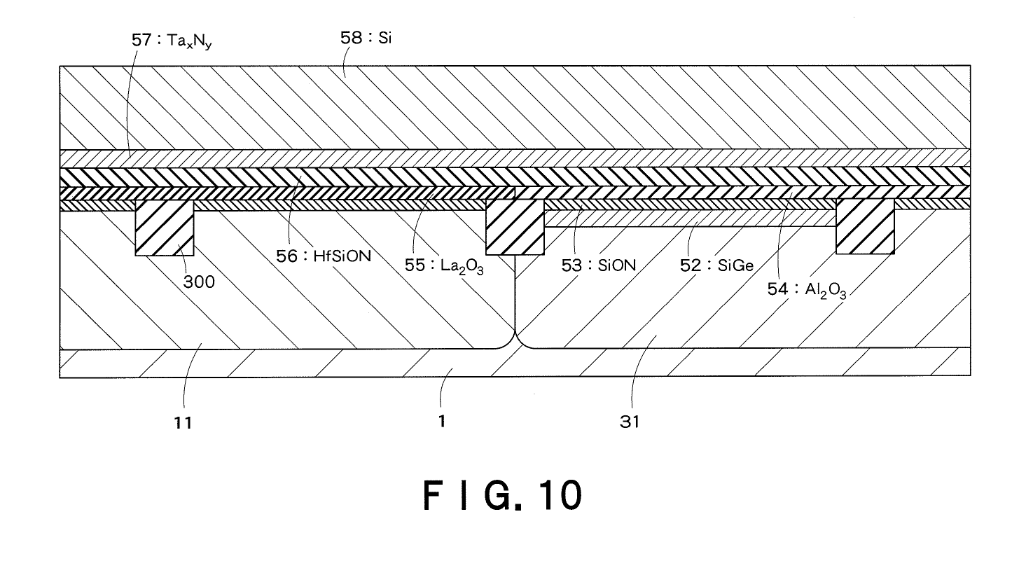

Then, a silicon film 58 is formed on the TaₓN_{y} film 57 (Step S8) to obtain the cross section structure shown in FIG. 10.

After that, by using a hard mask (not shown), the silicon film 58, the TaₓN_{y} film 57, the HfSiON film 56, the La₂O₃ film 55 (at the side of the P-type diffusion layer 11) and the Al₂O₃ film 54 (at the side of the N-type diffusion layer 31) are etched by an RIE (Reactive Ion Etching) manner. Because of this, formed are the SiON film 15 and the HfSiON film 17 which are the gate insulating film 102 of the NMOSFET 100, the La₂O₃ film 16 inserted between the SiON film 15 and the HfSiON film 17, and the TaₓN_{y} film 18 and the silicon film 19 which are the metal gate electrode 103. Furthermore, formed are the SiON film 35 and the HfSiON film 37 which are the gate insulating film 202 of the PMOSFET 200, the Al₂O₃ film 36 inserted between the SiON film 35 and the HfSiON film 37, and the TaₓN_{y} film 38 and the silicon film 39 which are the metal gate electrode 203 (Step S9). In this way, the cross section structure shown in FIG. 10 is obtained.

Because the materials of the metal gate electrode 103 of the NMOSFET 100 is the same as that of the metal gate electrode 203 of the PMOSFET 200, the manufacturing process can be simplified.

Then, by the ALD manner or the CVD manner, a SiN film is deposited to form the offset spacers 21 and 41. After that, by the CVD manner or the RIE manner, side wall spacers (not shown) made of SiO2 film are formed (Step S10).

Furthermore, by using a resist film (not shown) as a mask, B (boron) is implanted into the N-type diffusion layer 31 and P (phosphorus) or As (arsenic) is implanted into the P-type diffusion layer 11. Then, by performing the heat treatment, the P-type diffusion layer 32 is formed in the N-type diffusion layer 31, and the N-type diffusion layer 12 is formed in the P-type diffusion layer 11. Next, after removing the side wall spacers, by using a resist film (not shown) as a mask, the B is implanted into the N-type diffusion layer 31, and the P or the As is implanted into the P-type diffusion layer 11. By performing the heat treatment, the P-type extension diffusion layer 33 and the N-type extension diffusion layer 13 are formed (Step S11).

The N-type diffusion layer 12 and the N-type extension diffusion layer 13 become the source/drain electrode 101 of the NMOSFET 100. The P-type diffusion layer 32 and the P-type extension diffusion layer 33 become the source/drain electrode 201 of the PMOSFET 200.

By the heat treatment, a part of the nitrogen in the TaₓN_{y} films 18 and 38 diffuses into the HfSiON films 17 and 37 to decrease the threshold voltages Vth of the MOSFETs 100 and 200, respectively. Furthermore, a part of the tantalum in the TaₓN_{y} films 18 and 38 interfuses into the HfSiON films 17 and 37 respectively or the interface reactions between the part of the tantalum and the HfSiON films 17 and 37 occur. As a result, the gate insulating films 102 and 202 have the tantalum, the combinations between the tantalum and oxygen atoms in the HfSiON films 17 and 37 are generated.

Then, by the CVD manner and the RIE manner, formed are the side wall spacers 22 and 42 made of SiO₂ film and the side wall spacers 23 and 43 made of the SiN film. Next, the silicide films 21 and 41 are self-alignedly formed on the surface of the silicon film of the source/drain electrodes 101, 201 and the metal gate electrodes 103 and 203. In this way, the semiconductor device 500 having the cross section structure shown in FIG. 1 is obtained.

After that, interlayer insulating films are formed, contact holes are formed and filled with a conductive material, and wirings are formed and so on. Then, the semiconductor integrated circuit is formed.

As described above, in the first embodiment, the TaₓN_{y} films 18, 38 having the Ta₃N₅ is used as the materials of the metal gate electrodes 103 and 203. The TaₓN_{y} films 18, 38 have much nitrogen and a part thereof diffuses into the gate insulating films 102 and 202, which sets the flat band voltage Vfb higher than that of the TiN, thereby decreasing the threshold voltages Vth of the NMOSFET 100 and the PMOSFET 200. Furthermore, because the nitrogen in the TaₓN_{y} films 18, 38 diffuses into the HfSiON films 17 and 37 respectively, an insulating property of the gate insulating films 102 and 202 can be increased, thereby suppressing the leak current Jg.

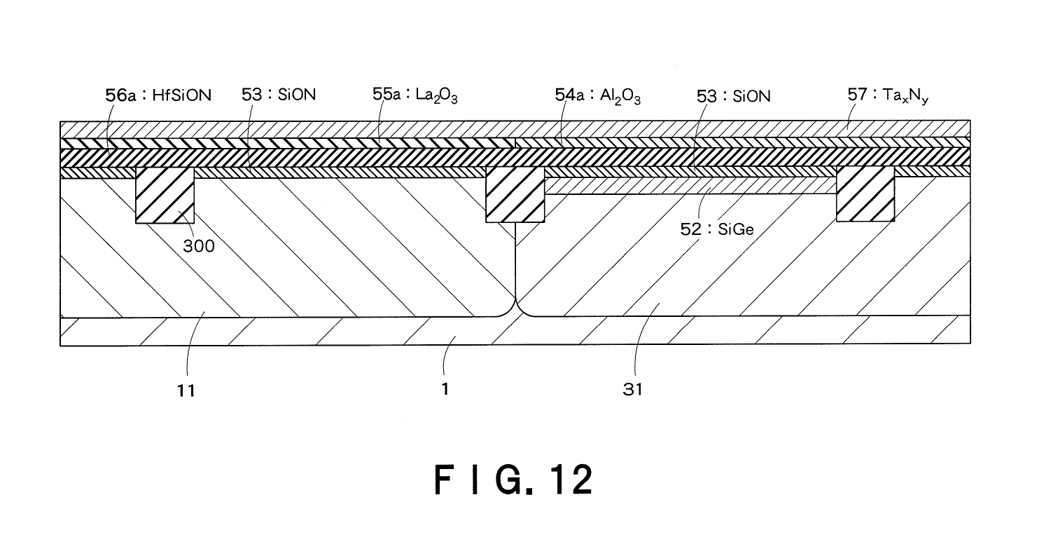

FIGS. 12 to 14 are sectional views of the semiconductor device in its manufacturing process, which are modified examples of FIG. 1. FIGS. 12 to 14 correspond to FIG. 9. In FIG. 9, in a case of the NMOSFET 100, the SiON film 53, the La₂O₃ film 55 and the HfSiON film 56 are sequentially formed from the channel side. In a case of the PMOSFET 200, the SiON film 53, the Al₂O₃ film 54 and the HfSiON film 56 are sequentially formed. Then, the TaₓN_{y} film 57, which becomes a metal gate electrode, is formed thereon.

On the other hand, in a first modified example of FIG. 12, in a case of the NMOSFET 100, the SiON film 53, the HfSiON film 56a and the La₂O₃ film 55a are sequentially formed from the channel side. In a case of the PMOSFET 200, the SiON film 53, the HfSiON film 56a and the Al₂O₃ film 54a are sequentially formed. Then, the TaₓN_{y} film 57 is formed thereon.

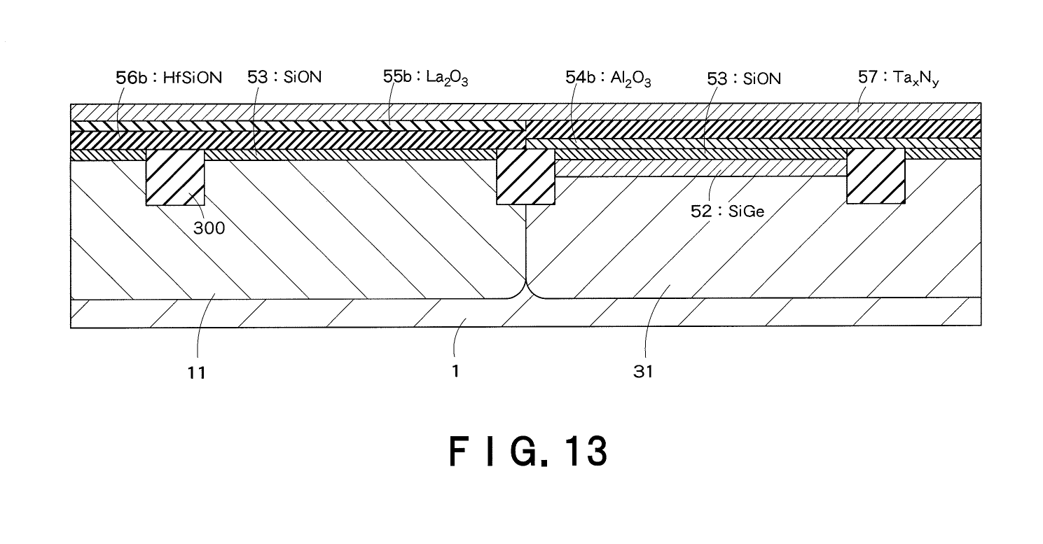

In a second modified example of FIG. 13, in a case of the NMOSFET 100, the SiON film 53, the HfSiON film 56b and the

La₂O₃ film 55b are sequentially formed from the channel side. In a case of the PMOSFET 200, the SiON film 53, the Al₂O₃ film 54b and the HfSiON film 56b are sequentially formed. Then, the TaₓN_{y} film 57 is formed thereon.

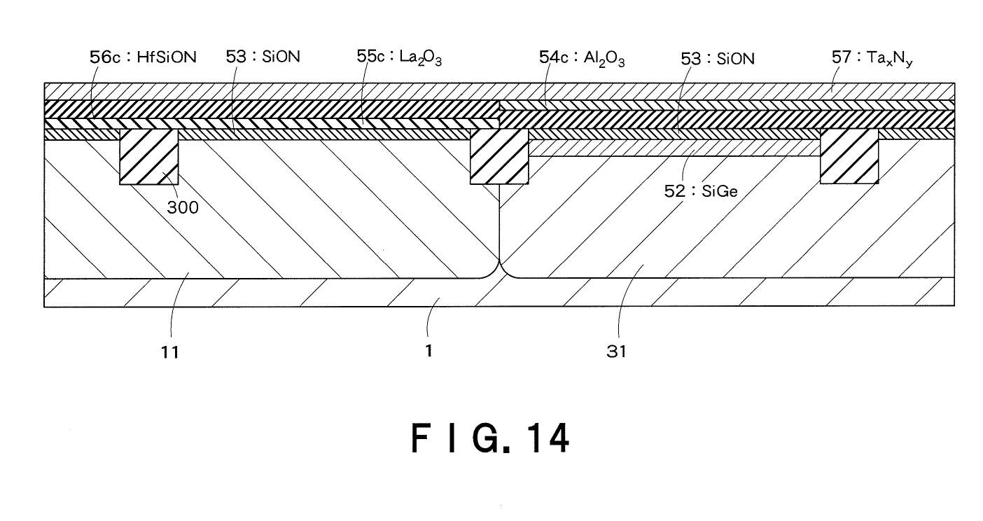

In a third modified example of FIG. 14, in a case of the NMOSFET 100, the SiON film 53, the La₂O₃ film 55c and the HfSiON film 56c are sequentially formed from the channel side. In a case of the PMOSFET 200, the SiON film 53, the HfSiON film 56c and the Al₂O₃ film 54c are sequentially formed. Then, the TaₓN_{y} film 57 is formed thereon.

As shown in FIGS. 12 to 14, the La₂O₃ film of the NMOSFET 100 and the Al₂O₃ film of the PMOSFET 200 can be inserted between the SiON film and the HfSiON film and can be inserted between the HfSiON film and the TaₓN_{y} film. Both cases can decrease the threshold voltage Vth and suppress the leak current Jg, as well as the NMOSFET 100 and the PMOSFET 200 of FIG. 1. When manufacturing the semiconductor device of FIGS. 12 to 14, orders of Steps S4 to S6 of FIG. 5 can be appropriately interchanged.

Furthermore, although in the present embodiment, after forming the N-type diffusion layer 12 and the P-type diffusion layer 32, the side wall spacers are removed, and then the N-type extension diffusion layer 13 and the P-type extension diffusion layer 33 are formed, right after forming the offset spacers 21 and 41, the N-type extension diffusion layer 13 and the P-type extension diffusion layer 33 can be formed, and then the side wall spacers can be formed, and then the N-type diffusion layer 12 and the P-type diffusion layer 32 can be formed.

### Second Embodiment

In a second embodiment, the metal gate electrode of the PMOSFET 200 has not only Al₂O₃ film but also La₂O₃ film.

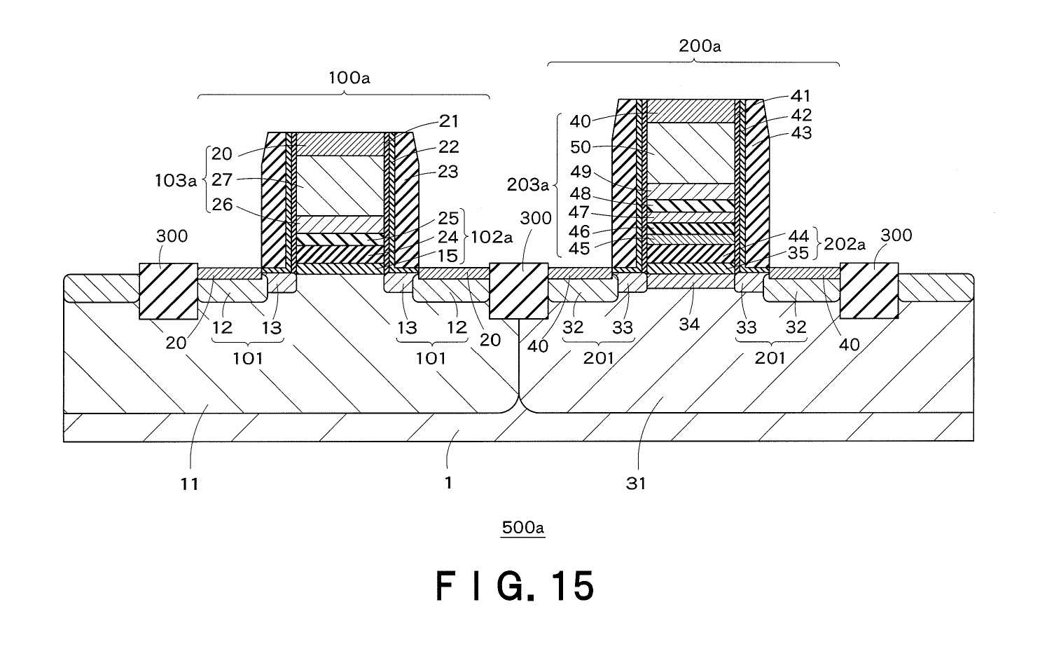

FIG. 15 is a sectional view of a semiconductor device 500a according to the second embodiment. In FIG. 15, components common to those of FIG. 1 have common reference numerals, respectively. Hereinafter, components different from FIG. 1 will be mainly described below.

The structures of the metal gate electrodes 103a and 203a of the NMOSFET 100a and the PMOSFET 200a are different from those of the NMOSFET 100 and the PMOSFET 200 of FIG. 1, respectively. The gate insulating film 102a of the NMOSFET 100a has a stacked structure of the SiON film 15, a HfSiON film 24 and a La₂O₃ film 25, and the metal gate electrode 103a has a stacked structure of a TaₓN_{y} film 26, a silicon film 27 and the silicide film 20.

On the other hand, the gate insulating film 202a of the

PMOSFET 200a has a stacked structure of the SiON film 35, a HfSiON film 44, and the metal gate electrode 203a has a stacked structure of a TaₓN_{y} film 45, a Al₂O₃ film 46, a TaₓN_{y} film 47, a La₂O₃ film 48, a TaₓN_{y} film 49, a silicon film 50 and the silicide film 40.

In the present embodiment, each of the TaₓN_{y} films 26, 45, 47, 49 has the Ta₃N₅. Therefore, comparing to forming films having different materials or different composition ratio, manufacturing process can be simplified, and the nitrogen in the TaₓN_{y} films 26, 45, 47, 49 surly diffuses into the gate insulating films 102a and 202a, thereby increasing the threshold voltage Vth of the MOSFET.

Incidentally, as described in the first embodiment, the La₂O₃ film 16 is inserted in order to decrease the EWF of the metal gate electrode 103 by approximately 0.5 eV in the NMOSFET 100 of FIG. 1. However, if there is a residual of the Al₂O₃ film on the La₂O₃ film 16, the EWF varies according to the amount of the residual. As well, the Al₂O₃ film 46 is inserted in order to increase the EWF of the metal gate electrode 203 by approximately 0.5 eV in the PMOSFET 200. However, if there is a residual of the La₂O₃ film on the Al₂O₃ film, the EWF varies according to the amount of the residual. Furthermore, if a part of the La₂O₃ diffuses into the Al₂O₃ film, the EWF varies according to the diffused amount. The variation of the EWF like this causes the variation of the threshold voltage Vth of the MOSFET.

Therefore, in the present embodiment, the semiconductor device 500a is manufactured by the following step to decrease the undesired residual.

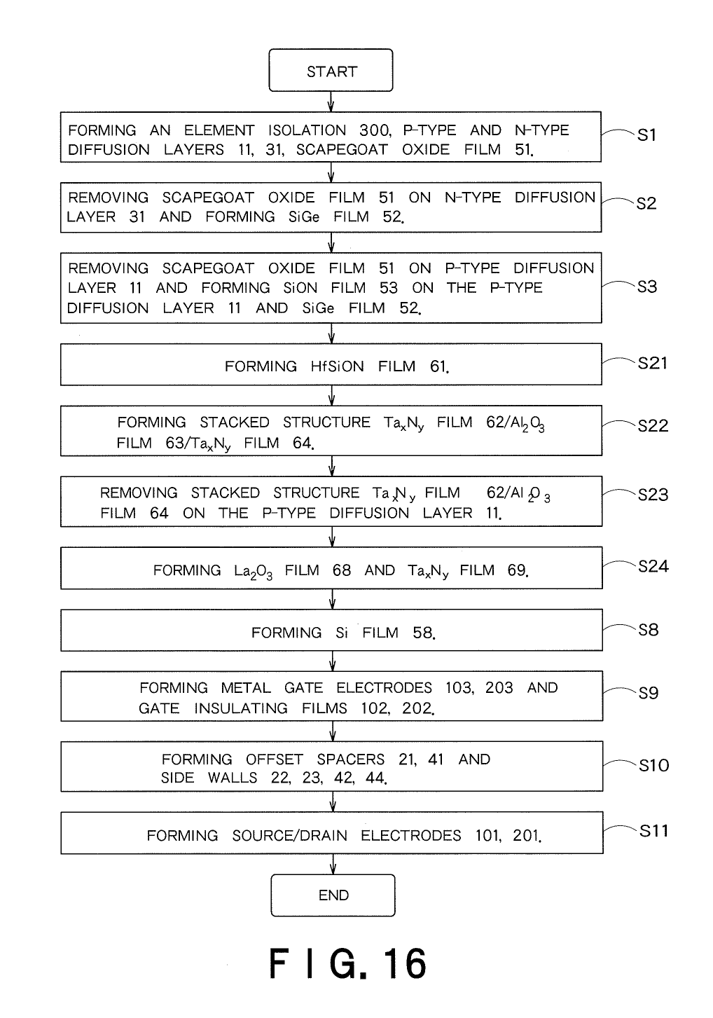

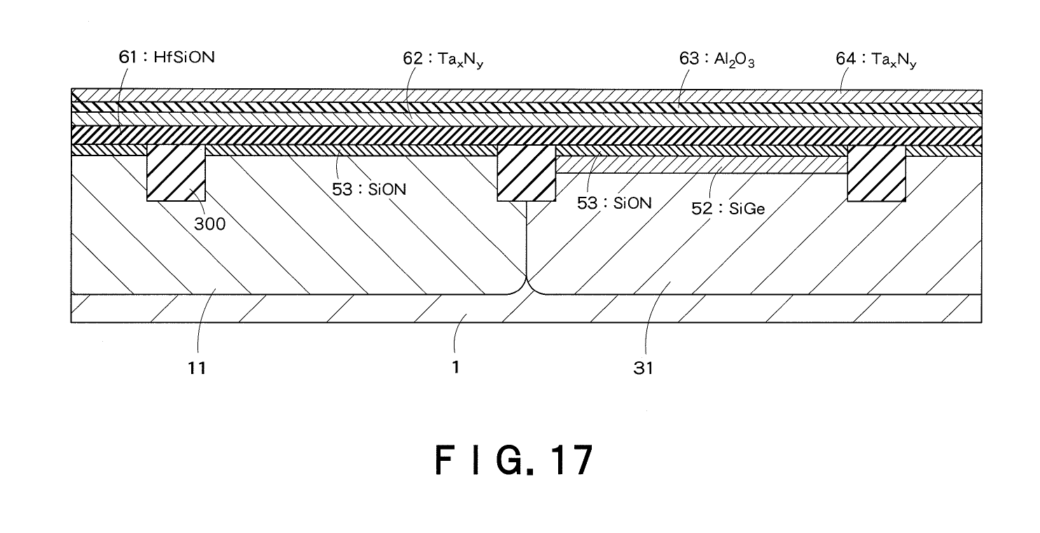

FIG. 16 is process chart showing the steps of a manufacturing process for the semiconductor device 500a of FIG. 15. Each of FIGS. 17 to 20 is sectional view of the semiconductor device in its manufacturing process.

Steps S1 to S3 are the same as those of the first embodiment shown in FIG. 5, and the cross section structure shown in FIG. 7 is obtained. After that, by the MOCVD manner, a HfSiO film is formed on the whole surface. Then, after the process under the atmosphere of the nitrogen plasma, the heat treatment is performed to mutate the HfSiO film into a HfSiON film 61 (Step S21). Furthermore, a TaₓN_{y} film 62 by the PVD manner, a Al₂O₃ film 63 by the ALD manner or the PVD manner, and a TaₓN_{y} film 64 by the PVD manner are sequentially formed on the whole surface (Step S22). In this way, the cross section structure shown in FIG. 17 is obtained.

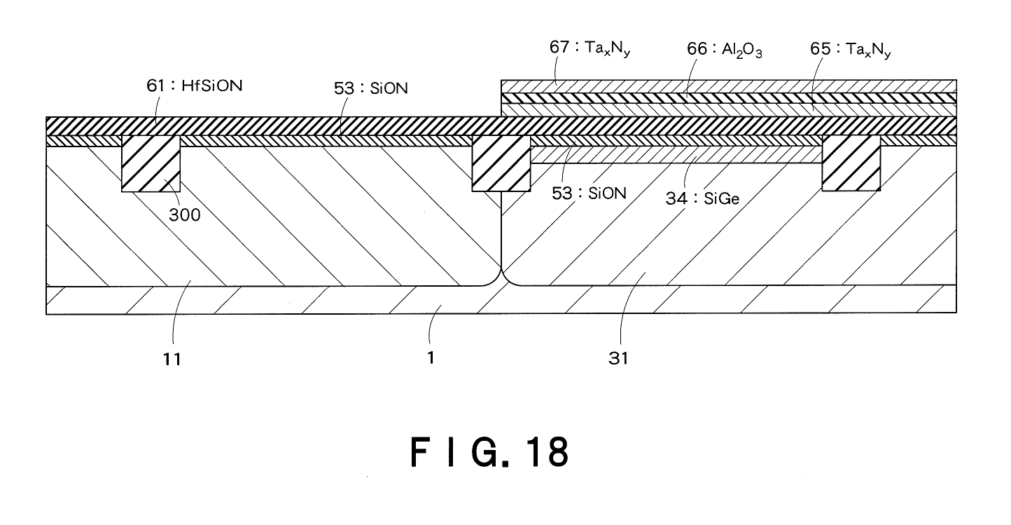

Then, by using a resist film (not shown) as a mask, the stacked structure of the TaₓN_{y} film 64/the Al₂O₃ film 63/the TaₓN_{y} film 62 above the P-type diffusion layer 11 is removed by etching (Step S23) to form the stacked structure of a TaₓN_{y} film 67/an Al₂O₃ film 66/a TaₓN_{y} film 65 only above the N-type diffusion layer 31. In this way, the cross section structure shown in FIG. 18 is obtained.

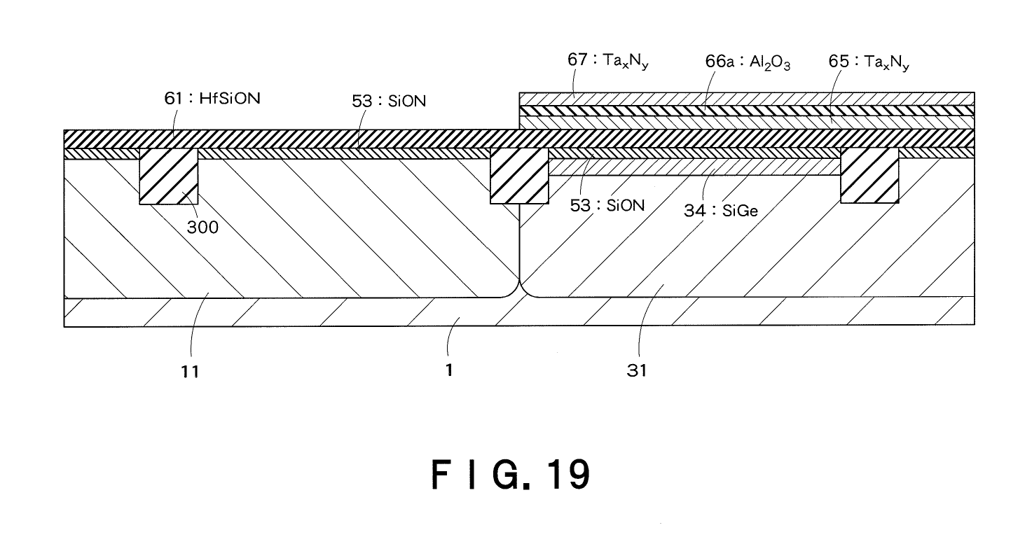

Note that, as shown in FIG. 19, by the PVD manner, an Al film 66a can be formed instead of the Al₂O₃ film 66. In this way, whole of the stacked structure can be formed by the PVD manner.

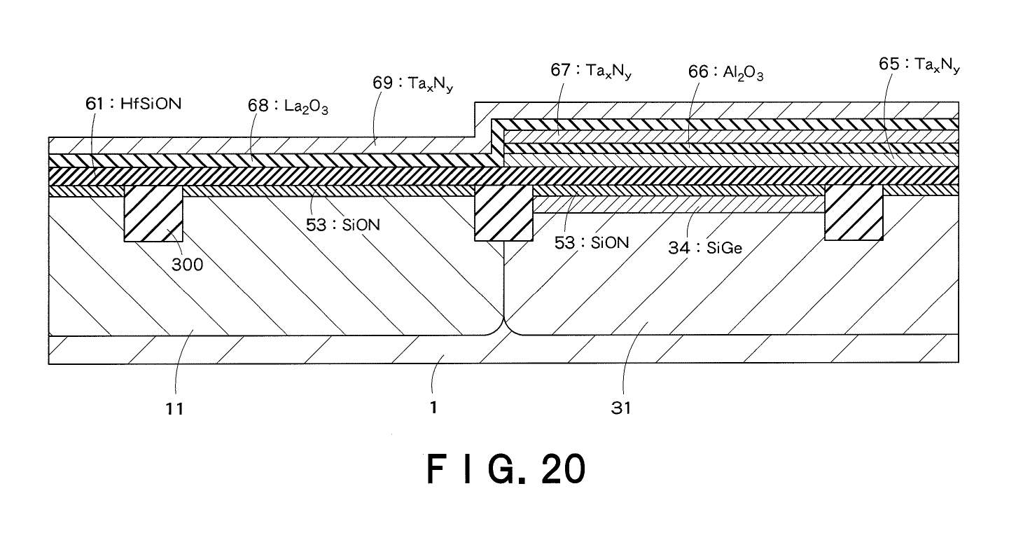

Then, by the PVD manner, a La₂O₃ film 68 and a TaₓN_{y} film 69 are formed on the whole surface (Step S24). In this way, the cross section structure shown in FIG. 20 is obtained.

Here, as shown in FIG. 17, the Al₂O₃ film 63 is not directly formed on the HfSiON film 61 above the P-type diffusion layer 11. Therefore, in FIG. 18 or FIG. 19, the La₂O₃ film 68 can be formed on the HfSiON film 61 without the residual of the Al₂O₃ film 63 on the HfSiON film 61 above the P-type diffusion layer 11.

Furthermore, because the TaₓN_{y} film 67 is formed on the Al₂O₃ film 66 above the N-type diffusion layer 31, the La₂O₃ film 68 formed above the N-type diffusion layer 31 does not diffuse into the Al₂O₃ film 66 and the EWF does not vary. Therefore, it is unnecessary to remove the La₂O₃ film 68 above the N-type diffusion layer 31 selectively, thereby simplifying the manufacturing process.

After that, a silicon film is formed on the TaₓN_{y} film 69

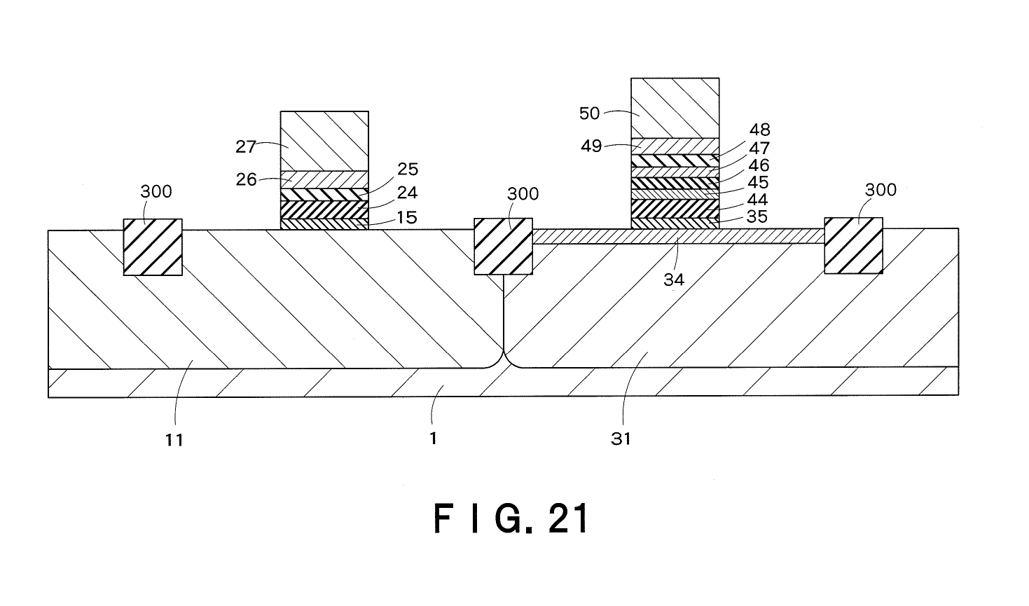

(Step S8), and the each formed layers are patterned to form the gate insulating films 102a and 202a and the metal gate electrodes 103a and 203a (Step S9). In this way, the cross section structure shown in FIG. 21 is obtained.

Then, by the process similar to the first embodiment of

FIG. 4, the semiconductor device 500a having the cross section structure shown in FIG. 15 is obtained.

In the present embodiment, the Al₂O₃ film 46 (or the Al film) is not in the gate insulating film 202a but in the metal gate electrode 203a. Also in this case, Al diffuses into the interface between the HfSiON film 44 and the SiON film 35 which form the gate insulating film 202a by the heat process. Therefore, the threshold voltage of the PMOSFET 200a can be decreased.

As described above, in the second embodiment, on manufacturing the NMOSFET 100a, the TaₓN_{y} film 62 is formed on the HfSiON film 61, and the Al₂O₃ film 63 for the PMOSFET 200a is formed on the TaₓN_{y} film 62. Therefore, the La₂O₃ film 68 is formed without the residual of the Al₂O₃. As a result, the EWF of the metal gate electrode 103a does not vary, and the threshold voltage Vth of the NMOSFET 100a can be decreased while keeping it constant.

On the other hand, on manufacturing the PMOSFET 200a, the TaₓN_{y} film 67 is formed on the Al₂O₃ film 66, and the La₂O₃ film 68 for the NMOSFET 100a is formed on the TaₓN_{y} film 67. Therefore, the La₂O₃ film 68 does not diffuse into the Al₂O₃ film 66. As a result, the EWF of the metal gate electrode 203a does not vary and the threshold voltage Vth of the PMOSFET 200a can be decreased while keeping it constant. Furthermore, because it is unnecessary to remove the La₂O₃ film 68, the manufacturing process can be simplified and the manufacturing cost can be suppressed.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fail within the scope and spirit of the inventions.

1. A semiconductor device comprising an N-type transistor and a P-type transistor,
wherein the N-type transistor comprises:
a first gate insulating film comprising a high dielectric film on a semiconductor substrate; and
a first gate electrode comprising a TaₓN_{y} film comprising Ta₃N₅ on the first gate insulating film;
wherein the first gate insulating film comprises a first material decreasing an effective work function of the first gate electrode,
the P-type transistor comprises:
a SiGe film on the semiconductor substrate;
a second gate insulating film comprising the high dielectric film on the SiGe film; and
a second gate electrode on the second gate insulating film, the second gate electrode being made of a material identical to a material of the first gate electrode;
wherein the second gate insulating film comprises a second material increasing an effective work function of the second gate electrode.

2. The device of claim 1, wherein the first material sets the effective work function of the first gate electrode close to a conduction band minimum of the semiconductor substrate, and
the second material sets the effective work function of the second gate electrode close to a valence band maximum of the semiconductor substrate.

3. The device of claim 1, wherein the first and the second gate insulating films comprise tantalum.

4. The device of claim 3, wherein a part of the tantalum in the TaₓN_{y} of the first and the second gate electrodes diffuses into the first and the second gate insulating films, respectively.

5. The device of claim 1, wherein the first and the second gate insulating films comprise nitrogen.

6. The device of claim 1, wherein the high dielectric film is HfSiON, the first material is La₂O₃, and the second material is Al₂O₃ or Al.

7. A semiconductor device comprising an N-type transistor and a P-type transistor,
wherein the N-type transistor comprises:
a first gate insulating film comprising a high dielectric film on a semiconductor substrate; and
a first gate electrode comprising a TaₓN_{y} comprising Ta₃N₅ film on the first gate insulating film;
wherein the first gate insulating film comprises a first material decreasing an effective work function of the first gate electrode,
the P-type transistor comprises:
a SiGe film on the semiconductor substrate;
a second gate insulating film comprising the high dielectric film on the SiGe film; and
a second gate electrode on the second gate insulating film;
wherein the second gate electrode comprises:
a first conducting film made of TaₓN_{y} on the second gate insulating film;
a second insulating film on the first conducting film, the second insulating film being made of a second material increasing an effective work function of the second gate electrode;
a third conducting film on the second insulating film, the third conducting film being made of a material identical to a material of the first conducting film;
a fourth insulating film on the third conducting film, the fourth insulating film being made of the first material; and
a fifth conducting film on the fourth insulating film, the fifth conducting film being made of a material identical to the material of the first conducting film.

8. The device of claim 7, wherein the first material sets the effective work function of the first gate electrode close to a conduction band minimum of the semiconductor substrate, and
the second material sets the effective work function of the second gate electrode close to a valence band maximum of the semiconductor substrate.

9. The device of claim 7, wherein the first and the second gate insulating films comprise tantalum.

10. The device of claim 9, wherein a part of the tantalum in the TaₓN_{y} of the first and the second gate electrodes diffuses into the first and the second gate insulating films, respectively.

11. The device of claim 7, wherein the first and the second gate insulating films comprise nitrogen.

12. The device of claim 7, wherein a part of the second material diffuses into the first gate insulating film.

13. The device of claim 7, wherein the high dielectric film is HfSiON, the first material is La₂O₃, and the second material is Al₂O₃ or Al.

14. A method for manufacturing a semiconductor device comprising:
forming a P-type diffusion layer on a place for forming an N-type transistor and forming an N-type diffusion layer on a place for forming a P-type transistor in a semiconductor substrate;
forming a SiGe film on the N-type diffusion layer;
forming a first insulating film on the P-type diffusion layer and on the SiGe film;
forming a second insulating film on the first insulating film on the P-type diffusion layer and forming a third insulating film on the first insulating film above the N-type diffusion layer;
forming a fourth insulating film on the second and the third insulating films, or between the first and the second insulting films and between the first and the third insulating films, the fourth insulating film being a high dielectric film;
forming a fifth conducting film on the fourth insulating film, or on the second and the third insulating films, the fifth insulating film being made of TaₓN_{y} comprising Ta₃N₅; and
forming gate insulating films of the N-type and P-type transistors by removing a part of the first to fourth insulating films, and forming gate electrodes of the N-type and P-type transistors by removing a part of the fifth conducting film;
wherein the second insulating film in the gate insulating film of the N-type transistor comprises a first material decreasing an effective work function of the gate electrode of the N-type transistor, and
the third insulating film in the gate insulating film of the P-type transistor comprises a second material increasing an effective work function of the gate electrode of the P-type transistor.

15. The method of claim 14, wherein upon forming the fifth conducting film, the fifth conducting film is formed by a reactive sputter manner in such a manner that at least the Ta₃N₅ is formed.

16. The method of claim 14 further comprising implanting impurities into the P-type and N-type diffusion layers and performing heat process to form source/drain electrodes of the N-type and P-type transistors and to diffuse a part of tantalum and a part of nitrogen in the fifth conducting film into the fourth insulating film after forming the gate electrodes.

17. The method of claim 14, wherein the first material sets the effective work function of the first gate electrode close to a conduction band minimum of the semiconductor substrate, and
the second material sets the effective work function of the second gate electrode close to a valence band maximum of the semiconductor substrate.

18. The method of claim 14, wherein the high dielectric film is HfSiON, the first material is La₂O₃, and the second material is Al₂O₃ or Al.
